(19) United States
(12) Patent Application Publication
(10) Pub. No.: US 2026/0344318 A1
(43) Pub. Date: Oct. 29, 2026

(54) ETCHING METHOD AND SUBSTRATE PROCESSING APPARATUS

(71) Applicant: Tokyo Electron Limited, Tokyo (JP)

(72) Inventor: Takayuki KATSUNUMA, Miyagi (JP)

(73) Assignee: Tokyo Electron Limited, Tokyo (JP)

(21) Appl. No.: 19/709,013

(22) Filed: Jun. 16, 2026

Related U.S. Application Data
(63) Continuation of application No. PCT/JP2024/040904, filed on Nov. 19, 2024.

(30) Foreign Application Priority Data
Dec. 27, 2023 (JP) 2023-220955

(51) Int. Cl. H10P 50/28; H10P 14/69; H10P 50/00

(52) U.S. Cl. CPC H10P 50/283; H10P 14/6902; H10P 50/73

(57) ABSTRACT

An etching method includes (a) providing a substrate including a silicon-containing layer including nitrogen and a mask on the silicon-containing layer, the mask including at least one opening; and (b) etching the silicon-containing layer to form a recess, (b) including (b1) etching the silicon-containing layer with a first plasma generated from a first processing gas including a fluorocarbon gas, the fluorocarbon gas having a highest flow rate among components of the first processing gas, and (b2) etching the silicon-containing layer with a second plasma generated from a second processing gas including a hydrogen fluoride gas.

### CROSS-REFERENCE TO RELATED APPLICATIONS

This application is a bypass continuation application of International Application No. PCT/JP2024/040904 having an international filing date of Nov. 19, 2024 and designating the United States, the International Application being based upon and claiming the benefit of priority from Japanese Patent Application No. 2023-220955, filed on Dec. 27, 2023, the entire contents of each of which are incorporated herein by reference.

### BACKGROUND

### Field

Exemplary embodiments of the present disclosure relate to an etching method and a substrate processing apparatus.

### Description of Related Art

JP 6990799 describes a technique for etching a silicon-containing film with a plasma generated from a processing gas.

### SUMMARY

An etching method according to one exemplary embodiment of the present disclosure includes (a) providing a substrate including a silicon-containing layer including nitrogen and a mask on the silicon-containing layer, the mask including at least one opening; and (b) etching the silicon-containing layer to form a recess, (b) including (b1) etching the silicon-containing layer with a first plasma generated from a first processing gas including a fluorocarbon gas, the fluorocarbon gas having a highest flow rate among components of the first processing gas, and (b2) etching the silicon-containing layer with a second plasma generated from a second processing gas including a hydrogen fluoride gas.

### BRIEF DESCRIPTION OF DRAWINGS

The scope of the present disclosure is best understood from the following detailed description of exemplary embodiments when read in conjunction with the accompanying drawings.

FIG. 1 is a diagram of a plasma processing system, illustrating an example structure.

FIG. 2 is a diagram of a plasma processing apparatus, illustrating an example structure.

FIG. 3 is a flowchart of an example of an etching method.

FIG. 4 is a diagram of a substrate in step ST1, illustrating an example cross-sectional structure.

FIG. 5 is a diagram of the substrate in step ST2, illustrating an example cross-sectional structure.

FIG. 6 is a flowchart of an example step ST2.

FIG. 7 is a diagram illustrating an example sidewall of a recess in step ST2-2.

FIG. 8 is a diagram illustrating an example sidewall of the recess in step ST2-1.

FIG. 9 is a diagram of the substrate at the end of step ST2, illustrating an example cross-sectional structure.

FIGS. 10A to 10D are diagrams illustrating images of substrates in an example and a comparative example.

FIG. 11 is a diagram of a substrate including two types of silicon-containing films in step ST1, illustrating example cross-sectional structures.

FIG. 12 is a diagram of the substrate including two types of silicon-containing films in step ST2, illustrating example cross-sectional structures.

### DETAILED DESCRIPTION

One or more embodiments of the present disclosure will be described below.

In one exemplary embodiment, an etching method includes (a) providing a substrate including a silicon-containing film comprising nitrogen and a mask on the silicon-containing film, and (b) etching the silicon-containing film to form a recess (hereinafter “film” means the same as “layer”). The mask includes at least one opening. The step (b) includes (b1) etching the silicon-containing film with a first plasma generated from a first processing gas including a fluorocarbon gas. The fluorocarbon gas has a highest flow rate among components of the first processing gas. The step (b) includes (b2) etching the silicon-containing film with a second plasma generated from a second processing gas including a hydrogen fluoride gas.

In one exemplary embodiment, the hydrogen fluoride gas has a highest flow rate among components of the second processing gas.

In one exemplary embodiment, the first processing gas is free of a hydrogen fluoride gas or includes a hydrogen fluoride gas having a lower flow rate than the hydrogen fluoride gas included in the second processing gas.

In one exemplary embodiment, the second processing gas is free of a fluorocarbon gas or includes a fluorocarbon gas having a lower flow rate than the fluorocarbon gas included in the first processing gas.

In one exemplary embodiment, the first processing gas includes two or more types of fluorocarbon gases with different composition ratios of fluorine to carbon.

In one exemplary embodiment, the second processing gas includes a fluorocarbon gas. The first processing gas includes the fluorocarbon gas with a higher composition ratio of fluorine to carbon than the fluorocarbon gas included in the second processing gas.

In one exemplary embodiment, at least one of the first processing gas or the second processing gas includes an oxygen-containing gas.

In one exemplary embodiment, at least one of the first processing gas or the second processing gas includes at least one gas selected from the group consisting of a noble gas, a nitrogen gas, a metal-containing gas, and a halogen-containing gas.

In one exemplary embodiment, (b) includes repeating a cycle including (b1) and (b2) a plurality of times.

In one exemplary embodiment, (b2) is performed after (b1).

In one exemplary embodiment, (b2) includes depositing a reaction product including nitrogen on a sidewall of the recess. The step (b1) includes removing the reaction product deposited on the sidewall of the recess.

In one exemplary embodiment, (b1) includes forming a carbon-containing film on a sidewall of the recess.

In one exemplary embodiment, the recess has a lower line edge roughness after (b1) than after (b2) performed immediately before (b1).

In one exemplary embodiment, a processing time of (b1) is same as or shorter than a processing time of (b2).

In one exemplary embodiment, a processing time of (b1) is longer than a processing time of (b2).

In one exemplary embodiment, (b) includes changing a ratio of a processing time of (b2) to a processing time of (b1) with progress of etching of the recess.

In one exemplary embodiment, the silicon-containing film includes at least one film selected from the group consisting of a silicon oxide film, a silicon nitride film, and a film stack including a silicon oxide film and a silicon nitride film.

In one exemplary embodiment, the silicon-containing film includes a first silicon-containing film and a second silicon-containing film different from the first silicon-containing film. The first silicon-containing film is a film stack including silicon oxide films and silicon nitride films alternately stacked on one another. The second silicon-containing film is a silicon oxide film.

In one exemplary embodiment, the mask includes at least one film selected from the group consisting of a silicon-containing film different from the silicon-containing film, a carbon-containing film, and a metal-containing film.

In one exemplary embodiment, a substrate processing apparatus includes a chamber, a substrate support in the chamber, a plasma generator, and a controller. The controller performs control operations including (a) providing a substrate onto the substrate support in the chamber, and (b) etching the silicon-containing film in the substrate provided on the substrate support to form a recess. The substrate includes a silicon-containing film containing nitrogen and a mask on the silicon-containing film. The mask includes at least one opening. The step (b) includes (b1) etching the silicon-containing film with a first plasma generated by the plasma generator from a first processing gas including a fluorocarbon gas. The fluorocarbon gas has a highest flow rate among components of the first processing gas. The step (b) includes (b2) etching the silicon-containing film with a second plasma generated by the plasma generator from a second processing gas including a hydrogen fluoride gas.

One or more embodiments of the present disclosure will now be described with reference to the drawings. In the drawings, like reference numerals denote the same or like components. Such components will not be described repeatedly. Unless otherwise specified, the positional relationships shown in the drawings are used to describe the vertical, lateral, and other positions. The drawings are not drawn to scale relative to the actual ratio of each component, and the actual ratio is not limited to the ratio in the drawings.

### First Embodiment

### Example of Plasma Processing System

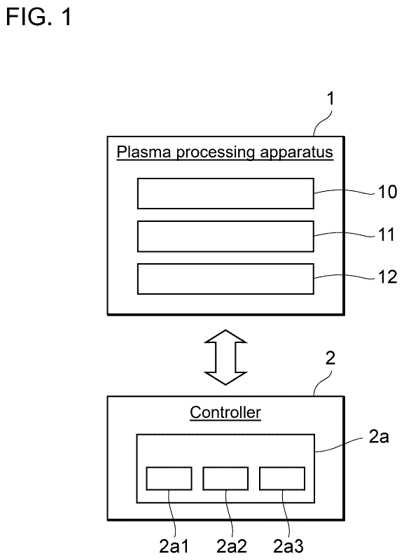

FIG. 1 is a diagram of a plasma processing system, illustrating an example structure. In one embodiment, the plasma processing system includes a plasma processing apparatus 1 and a controller 2 (herein “controller” means the same as “controller circuitry”). The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 also has at least one gas inlet for supplying at least one processing gas into the plasma processing space and at least one gas outlet for exhausting the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate.

The plasma generator 12 generates a plasma from at least one processing gas supplied into the plasma processing space. The plasma generated in the plasma processing space may be, for example, a capacitively coupled plasma (CCP), an inductively coupled plasma (ICP), an electron cyclotron resonance (ECR) plasma, a helicon wave plasma (HWP), or a surface wave plasma (SWP). The plasma generator 12 may be one of various plasma generators including an alternating current (AC) plasma generator and a direct current (DC) plasma generator. In one embodiment, an AC signal (AC power) used in the AC plasma generator has a frequency in a range of 100 kHz to 10 GHz. Thus, the AC signal may be a radio-frequency (RF) signal or a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the present disclosure. The controller 2 may cause the components of the plasma processing apparatus 1 to perform the various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2a1 may perform various control operations by loading programs from the storage 2a2 and executing the loaded programs. The programs may be prestored in the storage 2a2 or may be obtained through a medium as appropriate. The obtained programs are stored into the storage 2a2 to be loaded from the storage 2a2 and executed by the processor 2a1. The medium may be one of various storage media readable by the computer 2a or a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN). The controller/controller circuitry 2 can be programmable circuitry (e.g., embedded processor) or fixed circuitry (e.g., ASIC or PAL). In an exemplary embodiment, the controller/controller circuitry 2 can include one or more programmable processors/controllers.

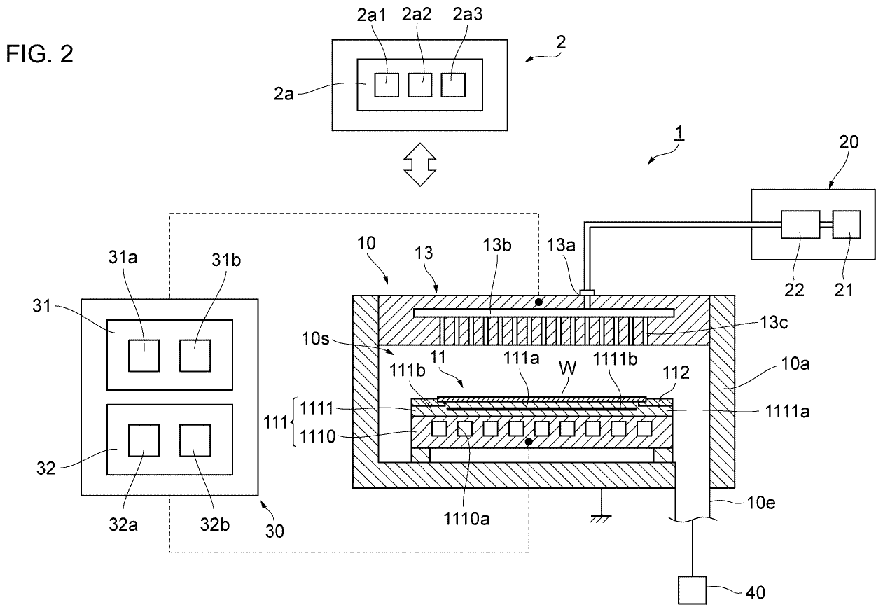

An example structure of a capacitively coupled plasma processing apparatus as an example of the plasma processing apparatus 1 will now be described. FIG. 2 is a diagram of the capacitively coupled plasma processing apparatus, illustrating an example structure.

The capacitively coupled plasma processing apparatus 1 includes the plasma processing chamber 10 (also simply referred to as a chamber), a gas supply 20, a power supply 30, and the exhaust system 40. The plasma processing apparatus 1 further includes the substrate support 11 and a gas introducer. The gas introducer allows at least one processing gas to be introduced into the plasma processing chamber 10. The gas introducer includes a showerhead 13. The substrate support 11 is located in the plasma processing chamber 10. The showerhead 13 is located above the substrate support 11. In one embodiment, the showerhead 13 defines at least a part of the ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 includes a central portion 111a for supporting a substrate W and an annular portion 111b for supporting the ring assembly 112. A wafer is an example of the substrate W. The annular portion 111b of the body 111 surrounds the central portion 111a of the body 111 as viewed in plan. The substrate W is placeable on the central portion 111a of the body 111. The ring assembly 112 is located on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may function as a lower electrode. The ESC 1111 is located on the base 1110. The ESC 1111 includes a ceramic member 1111a and an electrostatic electrode 1111b inside the ceramic member 1111a. The ceramic member 1111a includes the central portion 111a. In one embodiment, the ceramic member 1111a also includes the annular portion 111b. The annular portion 111b may be included in another member surrounding the ESC 1111, such as an annular ESC or an annular insulating member. In this case, the ring assembly 112 may be located on the annular ESC or the annular insulating member, or may be located on both the ESC 1111 and the annular insulating member. At least one RF/DC electrode coupled to an RF power supply 31 or a DC power supply 32, or both (described later) may be located inside the ceramic member 1111a. In this case, the RF/DC electrode functions as a lower electrode. When a bias RF signal or a DC signal, or both (described later) are provided to at least one RF/DC electrode, the RF/DC electrode is also referred to as a bias electrode. The conductive member in the base 1110 and at least one RF/DC electrode may function as multiple lower electrodes. The electrostatic electrode 1111b may also function as a lower electrode. The substrate support 11 thus includes at least one lower electrode.

The ring assembly 112 includes one or more annular members. In one embodiment, the one or more annular members include one or more edge rings and at least one cover ring. The edge rings are formed from a conductive material or an insulating material. The cover ring is formed from an insulating material.

The substrate support 11 may include a temperature controller that adjusts the temperature of at least one of the ESC 1111, the ring assembly 112, or the substrate to a target temperature. The temperature controller may include a heater, a heat transfer medium, a channel 1110a, or a combination of these. The channel 1110a carries a heat transfer fluid such as brine or a gas. In one embodiment, the channel 1110a is defined inside the base 1110, and one or more heaters are located inside the ceramic member 1111a in the ESC 1111. The substrate support 11 may include a heat transfer gas supply to supply a heat transfer gas into a space between the back surface of the substrate W and the central portion 111a.

The showerhead 13 introduces at least one processing gas from the gas supply 20 into the plasma processing space 10s. The showerhead 13 includes at least one gas inlet 13a, at least one gas-diffusion compartment 13b, and multiple gas guides 13c. The processing gas supplied to the gas inlet 13a passes through the gas-diffusion compartment 13b and is introduced into the plasma processing space 10s through the multiple gas guides 13c. The showerhead 13 further includes at least one upper electrode. In addition to the showerhead 13, the gas introducer may include one or more side gas injectors (SGIs) installed in one or more openings in the sidewall 10a.

The gas supply 20 may include at least one gas source 21 and at least one flow controller 22. In one embodiment, the gas supply 20 supplies at least one processing gas from each gas source 21 to the showerhead 13 through the corresponding flow controller 22. The flow controller 22 may be, for example, a mass flow controller or a pressure-based flow controller. The gas supply 20 may further include at least one flow rate modulator that causes at least one processing gas to be supplied at a modulated flow rate or in a pulsed manner.

The power supply 30 includes the RF power supply 31 coupled to the plasma processing chamber 10 through at least one impedance matching circuit. The RF power supply 31 provides at least one RF signal (RF power) to at least one lower electrode or at least one upper electrode, or both. This generates a plasma from at least one processing gas supplied into the plasma processing space 10s. The RF power supply 31 may thus function as at least a part of the plasma generator 12. A bias RF signal is provided to at least one lower electrode to generate a bias potential in the substrate W, thus drawing ion components in the generated plasma toward the substrate W.

In one embodiment, the RF power supply 31 includes a first RF generator 31a and a second RF generator 31b. The first RF generator 31a is coupled to at least one lower electrode or at least one upper electrode, or both through at least one impedance matching circuit to generate a source RF signal (source RF power) for plasma generation. In one embodiment, the source RF signal has a frequency in a range of 10 to 150 MHz. In one embodiment, the first RF generator 31a may generate multiple source RF signals with different frequencies. The one or more generated source RF signals are provided to at least one lower electrode or at least one upper electrode, or both.

The second RF generator 31b is coupled to at least one lower electrode through at least one impedance matching circuit to generate a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The one or more generated bias RF signals are provided to at least one lower electrode. In various embodiments, at least one of the source RF signal or the bias RF signal may be pulsed.

The power supply 30 may include the DC power supply 32 coupled to the plasma processing chamber 10. The DC power supply 32 includes a first DC generator 32a and a second DC generator 32b. In one embodiment, the first DC generator 32a is coupled to at least one lower electrode to generate a first DC signal. The generated first DC signal is applied to at least one lower electrode. In one embodiment, the second DC generator 32b is coupled to at least one upper electrode to generate a second DC signal. The generated second DC signal is applied to at least one upper electrode.

In various embodiments, the first DC signal and the second DC signal may be pulsed. In this case, the sequence of voltage pulses is applied to at least one lower electrode or at least one upper electrode, or both. The voltage pulses may have rectangular, trapezoidal, or triangular pulse waveforms, or a combination of these. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 may include the first DC generator 32a and the second DC generator 32b in addition to the RF power supply 31 or may include the first DC generator 32a in place of the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may be a turbomolecular pump, a dry pump, or a combination of these.

### Example of Etching Method

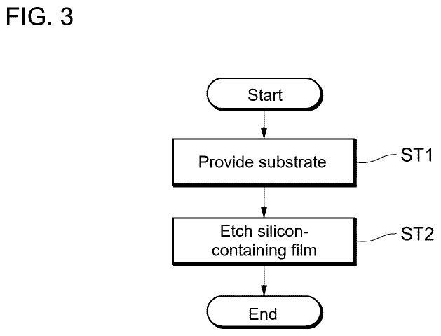

FIG. 3 is a flowchart of an example of an etching method (hereafter also referred to as the processing method) according to an exemplary embodiment. In one embodiment, the processing method includes step ST1 and step ST2 as shown in FIG. 3. Step 1 includes providing a substrate. Step ST2 includes etching a silicon-containing film in the substrate to form a recess. The processing in each step may be performed in the plasma processing system shown in FIG. 2. An example in which the controller 2 causes the components of the plasma processing apparatus 1 to perform the processing method on the substrate W will be described.

### Step ST1: Providing Substrate

In one embodiment, the substrate W is provided into the plasma processing chamber 10 (hereafter also referred to as a chamber 10) in step ST1 as shown in FIG. 2. In one embodiment, the substrate W may be loaded into the chamber 10 with a transfer arm, placed onto the substrate support 11 with a lifter, and clamped on the substrate support 11.

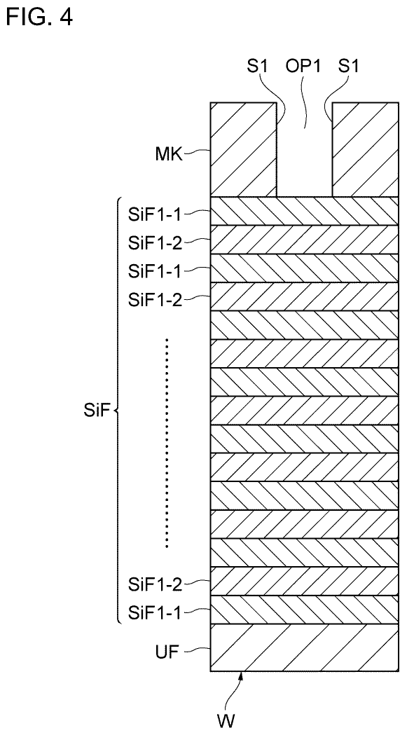

FIG. 4 is a diagram of the substrate W provided in step ST1, illustrating an example cross-sectional structure. The substrate W includes an underlying film UF, a silicon-containing film SiF on the underlying film UF, and a mask MK on the silicon-containing film SiF. The substrate W may be used for manufacturing semiconductor devices. Examples of the semiconductor devices include semiconductor memory devices such as a dynamic RAM (DRAM) and a three-dimensional NOT-AND (3D-NAND) flash memory, and a logic device.

In one embodiment, the underlying film UF may be, for example, a silicon wafer or an organic film, a dielectric film, a metal film, or a semiconductor film on the silicon wafer. The underlying film UF may include multiple films stacked on one another.

In one embodiment, the silicon-containing film SiF is a target film of etching with the processing method. In one embodiment, the silicon-containing film SiF may contain nitrogen. The silicon-containing film SiF may be a film stack including two or more different types of silicon-containing films. The silicon-containing film SiF may be a film stack including silicon oxide films SiF1-1 and silicon nitride films SiF1-2 alternately stacked on one another. The silicon-containing film SiF may be a film stack including 20 or more films, 50 or more films, or 100 or more films.

In one embodiment, the mask MK functions as a mask during etching of the silicon-containing film SiF. The mask MK may be a film including at least one selected from the group consisting of a silicon-containing film, a carbon-containing film, and a metal-containing film. The silicon-containing film in the mask MK may be different from the silicon-containing films included in the silicon-containing film SiF. The carbon-containing film in the mask MK may be an amorphous carbon layer (ACL) or a spin-on carbon (SOC) film. The metal-containing film in the mask MK may be a film containing at least one selected from the group consisting of tungsten, molybdenum, titanium, and ruthenium. The metal-containing film in the mask MK contains at least one selected from the group consisting of tungsten silicide (WSi), tungsten carbide (WC), tungsten silicon carbide (WSiC), and tungsten silicon nitride (WSiN). The mask MK may be a single layer mask including one film or a multilayer mask including two or more films.

The mask MK may have a sidewall S1 defining at least one opening OP1 on an etching target film EF. More specifically, the mask MK may include the opening OP1. The opening OP1 may be a space on the silicon-containing film SiF, surrounded by the sidewall S1 of the mask MK.

The opening OP1 may have any feature in a plan view of the substrate W, or in other words, when the substrate W is viewed from the top to the bottom in FIG. 4. The opening feature may be, for example, a circle, an oval, a rectangle, a line, or a combination of one or more of these features. The mask MK may have multiple sidewalls S1, which may define multiple openings OP1. The openings OP1 may be slits arranged in a pattern of lines and spaces at regular intervals or different intervals. The openings OP1 may be holes in a patterned array.

The films included in the substrate W (the underlying film UF, the silicon-containing film SiF, and the mask MK) may each be formed by any method. The underlying film UF, the silicon-containing film SiF, and the mask MK may each be formed by chemical vapor deposition (CVD), atomic layer deposition (ALD), molecular layer deposition (MLD), physical vapor deposition (PVD), spin coating, or other methods. The opening OP1 in the mask MK may be formed by etching. The opening OP1 in the mask MK may be formed by lithography. Each film may be a flat film or an uneven film. The substrate W may further include another film under the underlying film UF.

The process of forming the underlying film UF, the silicon-containing film SiF, and the mask MK included in the substrate W may be at least partly performed in the plasma processing chamber 10 as part of step ST1. For example, the opening OP1 in the mask MK is formed by etching in step ST1. In this case, etching the mask MK in step ST1 may be sequentially followed by step ST2 (described later) in the chamber 10. In one embodiment, all or some of the films included in the substrate W may be formed in an apparatus or a chamber external to the plasma processing apparatus 1. The resultant substrate W may then be provided into the chamber 10.

In one embodiment, the temperature of the substrate support 11 or the substrate W may be controlled to a given temperature by a temperature controller. Controlling the temperature of the substrate support 11 or the substrate W to a given temperature includes causing the temperature of the heat transfer fluid flowing in the channel 1110a or the temperature of the heater to be the given temperature, or to be a temperature different from the given temperature. The given temperature may be, for example, 50 °C or lower, and −50 °C or higher. The given temperature may be 0 ° C. or lower. The temperature of the substrate support 11 or the substrate W may start to be controlled to the given temperature before, after, or at the same time as the substrate W is provided onto the substrate support 11. The temperature of the substrate support 11 or the substrate W may be changed in each of step ST1, step ST2-1, and step ST2-2.

### Step ST2: Etching

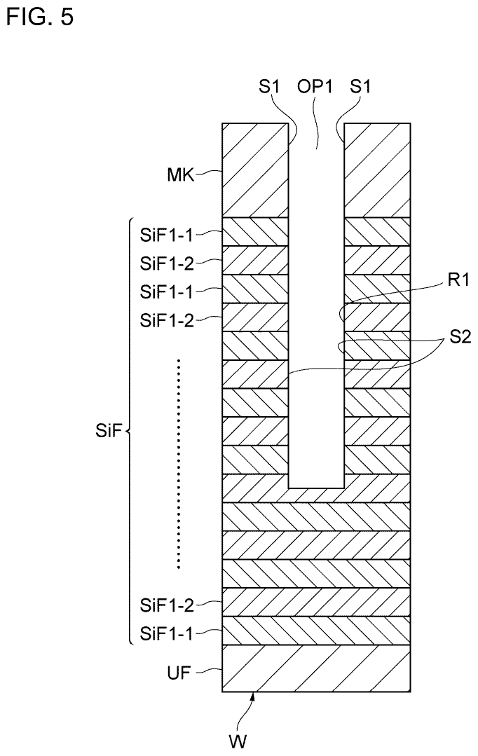

FIG. 5 is a diagram of the substrate W in step ST2, illustrating an example cross-sectional structure. In one embodiment, a plasma generated from a processing gas is used for etching the silicon-containing film SiF to form a recess R1 in the silicon-containing film SiF in step ST2.

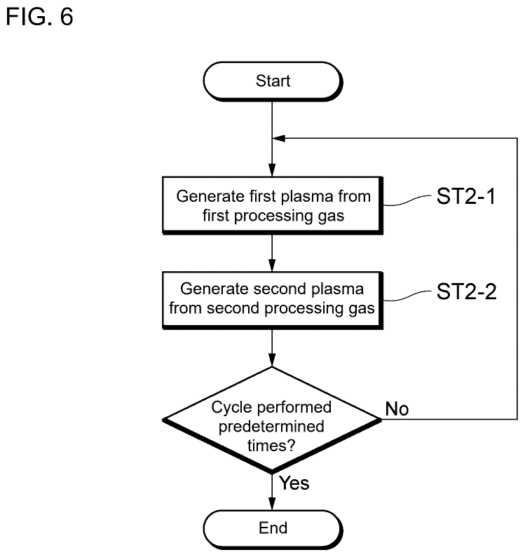

FIG. 6 is a flowchart of an example step ST2. In one embodiment, step ST2 includes step ST2-1 and step ST2-2 as shown in FIG. 6. Step ST2-1 includes etching the silicon-containing film with a first plasma generated from a first processing gas including a fluorocarbon gas. Step ST2-2 includes etching the silicon-containing film with a second plasma generated from a second processing gas including a hydrogen fluoride gas.

In one embodiment, the first processing gas is supplied into the plasma processing space 10s through the showerhead 13 shown in FIG. 2 in step ST2-1. The first processing gas includes a fluorocarbon gas. The fluorocarbon gas has the highest flow rate among gas species in the first processing gas. The first processing gas may be free of a hydrogen fluoride gas. The first processing gas may include a hydrogen fluoride gas having a lower flow rate (partial pressure) than the hydrogen fluoride gas included in the second processing gas (described later).

The first processing gas may include two or more types of fluorocarbon gases with different composition ratios of fluorine to carbon (F/C). The first processing gas may include a C₄F₆ gas and a C₄F₈ gas as fluorocarbon gases. The first processing gas may include at least one gas selected from the group consisting of a C₄F₆ gas, a C₄F₈ gas, a C₃F₈ gas, a CF₄ gas, a C₃F₆ gas, a C₂F₂ gas, a C₂F₄ gas, and a C₅F₈ gas as a fluorocarbon gas. The first processing gas may include at least one of a hydrofluorocarbon gas (CHF) or a hydrocarbon (CH) gas. When the second processing gas (described later) includes a fluorocarbon gas, the first processing gas may include a fluorocarbon gas with a higher composition ratio of fluorine to carbon (F/C) than the fluorocarbon gas included in the second processing gas.

The first processing gas may further include an oxygen-containing gas. The first processing gas may include at least one gas selected from the group consisting of an O₂ gas, a CO gas, and a CO₂ gas as an oxygen-containing gas.

The first processing gas may further include at least one gas selected from the group consisting of a noble gas, a nitrogen gas, a metal-containing gas, and a halogen-containing gas. The first processing gas may include at least one gas selected from the group consisting of an Ar gas, a He gas, and a Kr gas as a noble gas. The first processing gas may include a WF₆ gas as a metal-containing gas. The first processing gas may include at least one gas selected from the group consisting of a HBr gas, a HCl gas, a Cl₂ gas, and a boron-containing gas (BCl₃ gas) as a halogen-containing gas. The first processing gas may include a halogen-containing gas free of fluorine.

The temperature of the substrate support 11 or the substrate W may be controlled to a first temperature. The first temperatures may be 0 °C or lower, or −10 °C or lower. The pressure in the chamber 10 may be adjusted to a first pressure. The first pressure may be in a range of 1 to 1000 mTorr inclusive or 1 to 100 mTorr inclusive.

In one embodiment, the first plasma is generated from the first processing gas supplied into the chamber 10. In this case, a source RF signal is provided from the power supply 30 to the upper electrode or the lower electrode, or both. This generates an RF electric field above the substrate support 11 and generates the first plasma from the first processing gas in the plasma processing space 10s. The source RF signal may have a frequency of 1 kHz or higher, 1 MHz or higher, or 13 MHz or higher. The source RF signal may have first power. The first power may be 1 kW or higher.

A bias signal may be provided to the substrate support 11 during plasma generation. The bias signal may be a bias RF signal provided from the RF power supply 31 or a bias DC signal provided from the DC power supply 32. The bias DC signal may be a DC pulse signal. This generates a bias potential between the plasma and the substrate W. Active species such as ions and radicals in the plasma are drawn toward the substrate W, etching the silicon-containing film SiF. Step ST2-1 includes etching the bottom of the recess R1 in the depth direction. Step ST2-1 includes forming a carbon-containing film on a sidewall S2 of the recess R1. Step ST2-1 includes removing a reaction product deposited on the sidewall S2 of the recess R1.

In one embodiment, the second processing gas is supplied into the plasma processing space 10s through the showerhead 13 shown in FIG. 2 in step ST2-2. The second processing gas includes a hydrogen fluoride (HF) gas. The hydrogen fluoride gas has the highest flow rate among gas species in the second processing gas. The second processing gas may be free of a fluorocarbon gas. The second processing gas may include a fluorocarbon gas having a lower flow rate (partial pressure) than the fluorocarbon gas included in the first processing gas.

The second processing gas may include a C₄F₆ gas as a fluorocarbon gas. The second processing gas may include a fluorocarbon gas with a lower composition ratio of fluorine to carbon (F/C) than the fluorocarbon gas included in the first processing gas. The second processing gas may include at least one gas selected from the group consisting of a C₄F₆ gas, a C₄F₈ gas, a C₃F₈ gas, a CF₄ gas, a C₃F₆ gas, a C₂F₂ gas, a C₂F₄ gas, and a C₅F₈ gas as a fluorocarbon gas. The second processing gas may include at least one of a CHF gas or a CH gas.

The second processing gas may further include an oxygen-containing gas. The second processing gas may further include at least one gas selected from the group consisting of an O₂ gas, a CO gas, and a CO₂ gas as an oxygen-containing gas.

The second processing gas may further include at least one gas selected from the group consisting of a noble gas, a nitrogen gas, a metal-containing gas, and a halogen-containing gas. The second processing gas may include at least one gas selected from the group consisting of an Ar gas, a He gas, and a Kr gas as a noble gas. The second processing gas may include a WF₆ gas as a metal-containing gas. The second processing gas may include at least one gas selected from the group consisting of a HBr gas, a HCl gas, a Cl₂ gas, and a boron-containing gas (BCl₃ gas) as a halogen-containing gas. The second processing gas may include a halogen-containing gas free of fluorine. The second processing gas may include a phosphorus-containing gas. The second processing gas may include at least one gas selected from the group consisting of a PF₃ gas, a PCl₃ gas, a PF₅ gas, a PCl₅ gas, a POCl₃ gas, a PH₃ gas, a PBr₃ gas, and a PBr₅ gas as a phosphorus-containing gas.

The temperature of the substrate support 11 or the substrate W may be controlled to a second temperature. The second temperature may be 0 °C or lower, or −10 °C or lower. The pressure in the chamber 10 may be adjusted to a second pressure. The second pressure may be in a range of 1 to 1000 mTorr inclusive or 1 to 100 mTorr inclusive.

In one embodiment, the second plasma is generated from the second processing gas supplied into the chamber 10. In this case, a source RF signal is provided from the power supply 30 to the upper electrode or the lower electrode, or both. This generates an RF electric field above the substrate support 11 and generates the first plasma from the first processing gas in the plasma processing space 10s. The source RF signal may have a frequency of 1 kHz or higher, 1 MHz or higher, or 13 MHz or higher. The source RF signal may have second power. The second power may be 1 kW or higher.

A bias signal may be provided to the substrate support 11 during plasma generation. The bias signal may be a bias RF signal provided from the RF power supply 31 or a bias DC signal provided from the DC power supply 32. The bias DC signal may be a DC pulse signal. This generates a bias potential between the plasma and the substrate W. Active species such as ions and radicals in the plasma are drawn toward the substrate W, etching the silicon-containing film SiF. Step ST2-2 includes etching the bottom of the recess R1 in the depth direction. Step ST2-2 includes depositing a reaction product containing nitrogen on the sidewall S2 of the recess R1.

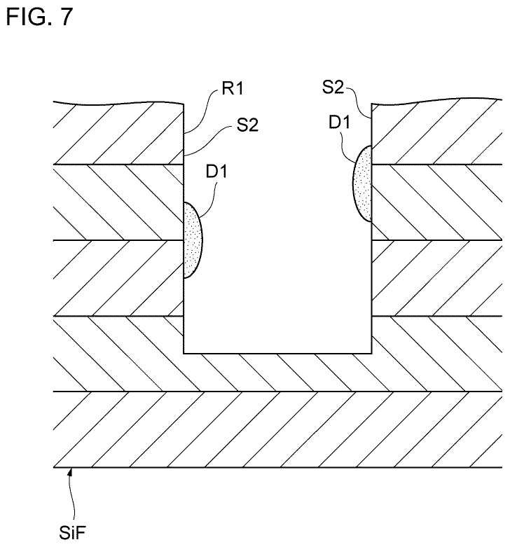

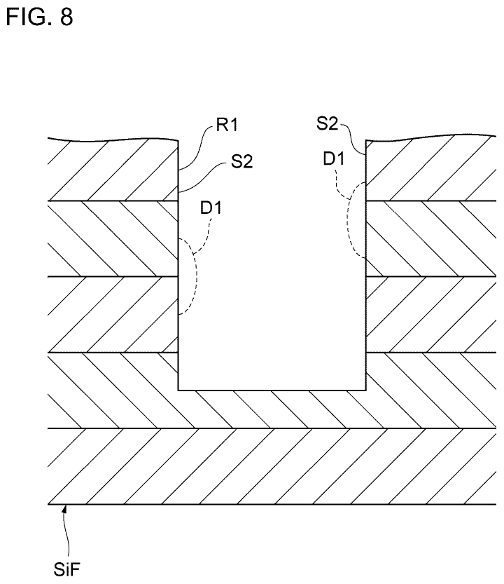

In one embodiment, a cycle including step ST2-1 and step ST2-2 is performed multiple times as shown in FIG. 6. In step ST2-2, a reaction product D1 containing nitrogen may be deposited on the sidewall S2 of the recess R1 as shown in FIG. 7. In step ST2-1, the reaction product D1 deposited on the sidewall S2 of the recess R1 may be removed as shown in FIG. 8. The reaction product D1 may contain ammonium hexafluorosilicate (AFS).

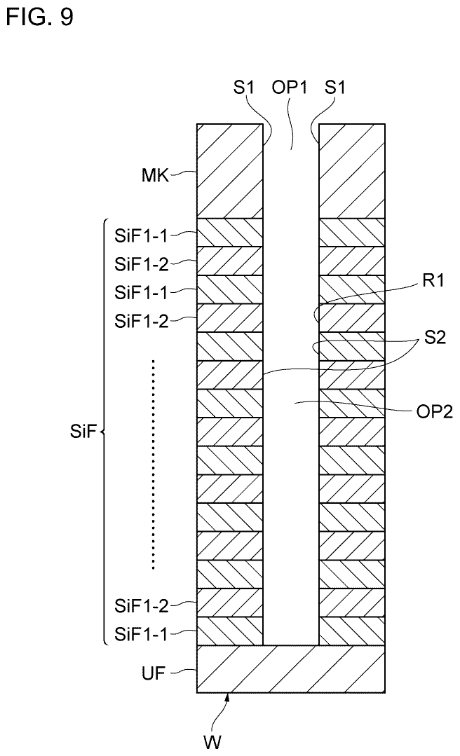

When the cycle including step ST2-1 and step ST2-2 is not performed a predetermined number of times, the cycle is repeated as shown in FIG. 6. When the cycle including step ST2-1 and step ST2-2 is performed the predetermined number of times, step ST2 may end, and the processing method may end. In this case, the silicon-containing film SiF may have an opening OP2 through which the underlying film UF is exposed as shown in FIG. 9. The predetermined number of times the cycle is performed may be two times or greater, five times or greater, 10 times or greater, 20 times or greater, 30 times or greater, or 40 times or greater. The predetermined number of times the cycle is performed may be once.

The cycle may include step ST2-1 and step ST2-2 in this order. The cycle may include step ST2-2 and step ST2-1 in this order. In other words, either of step ST2-1 or step ST2-2 may be performed first. The cycle may be performed at intervals of 100 seconds or less or at intervals of 50 seconds or less. In one embodiment, the intervals for the cycle may be changed as the etching of the recess progresses in step ST2. The cycle may be performed at longer intervals or at shorter intervals as the etching of the recess progresses.

In one embodiment, step ST2-1 may have a processing time (plasma generation time) that is the same as or shorter than the processing time in step ST2-2. The ratio of the processing time in step ST2-1 to the processing time in step ST2-2 may be 1:1 to 1:4. Step ST2-1 may have a longer processing time than step ST2-2. In one embodiment, the ratio of the processing time in step ST2-2 to the processing time in step ST2-1 may be changed as the etching of the recess progresses in step ST2. The ratio of the processing time in step ST2-2 to the processing time in step ST2-1 may be increased as the etching of the recess progresses. The ratio of the processing time in step ST2-2 to the processing time in step ST2-1 may be decreased as the etching of the recess progresses. In step ST2 (step ST2-1 and step ST2-2), the gas supplied into the chamber 10 may be switched between the first processing gas and the second processing gas while the source RF signal for plasma generation is being continuously provided to the upper electrode or the lower electrode. During this operation, the plasma may be generated continuously. The ratio of the supply time of the first processing gas (processing time in step ST2-1) to the supply time of the second processing gas (processing time in step ST2-2) may be 1:1 to 1:100. The ratio of the supply time of the first processing gas to the supply time of the second processing gas may be 1:2 to 1:80 or 1:3 to 1:70.

After step ST2, the substrate W may be unloaded outside from the chamber 10. In one embodiment, the substrate W may be unloaded from the substrate support 11 outside the chamber 10 with the lifter and the transfer arm. The processing method may thus end.

The substrate processing method according to the exemplary embodiment includes (a) providing a substrate W including a silicon-containing film SiF containing nitrogen and a mask MK on the silicon-containing film SiF, and (b) etching the silicon-containing film SiF to form a recess R1. The step (b) includes (b1) etching the silicon-containing film SiF with a first plasma generated from a first processing gas including a fluorocarbon gas, which has a highest flow rate among the components of the first processing gas, and (b2) etching the silicon-containing film SiF with a second plasma generated from a second processing gas including a hydrogen fluoride gas. A reaction product D1 containing nitrogen is produced during etching of the silicon-containing film SiF containing nitrogen. The generated reaction product D1 may be deposited on a sidewall S2 of the recess R1. In the present embodiment, for example, (b-1) causes the reaction product D1 on the sidewall S2 of the recess R1 to be removed. The reaction product deposited on the sidewall S2 of the recess R1 is thus less likely to interfere with etching of the silicon-containing film SiF. This reduces irregular features during etching.

### Example 1

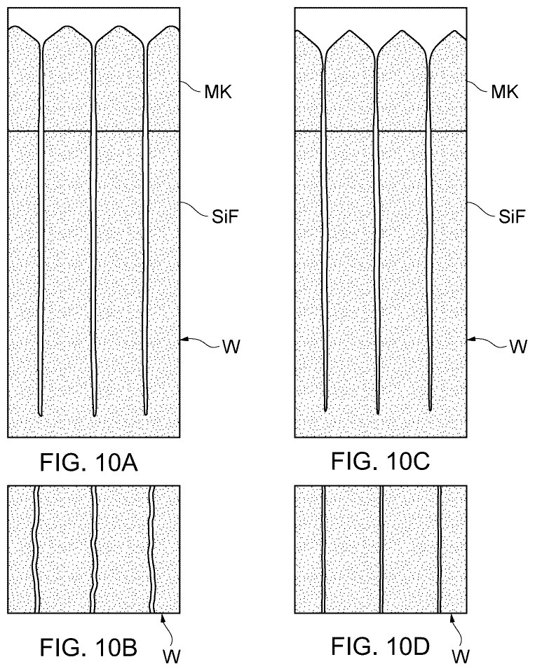

FIG. 10A is a diagram illustrating a cross-sectional image of a substrate including a silicon-containing film in Comparative Example 1. FIG. 10B is a diagram illustrating a top image of the substrate near its bottom after removal of the silicon-containing film in FIG. 10A. FIG. 10C is a diagram illustrating a cross-sectional image of a substrate including a silicon-containing film in Example 1. FIG. 10D is a diagram illustrating a top image of the substrate near its bottom after removal of the silicon-containing film in FIG. 10C. FIGS. 10A to 10D are based on images captured with a scanning electron microscope. In each of Example 1 and Comparative Example 1, the silicon-containing film SiF on the substrate W included multiple slits.

In Comparative Example 1, step ST2-2 alone was performed during etching. Comparative Example 1 was performed under condition A described below.

### Condition A

Source RF signal: 5.5 kW (40 MHz)
Bias signal: 9 kV (400 kHz)
Second processing gas: an HF gas, a fluorocarbon gas (C₄F₆ gas), an O₂ gas, and a halogen gas
Processing temperature: −20 °C

In Example 1, step ST2-1 and step ST2-2 were performed during etching. In Example 1, a cycle including processing under condition B-1 and processing under condition B-2 performed in this order was repeated 10 times. The conditions are described below.

### Condition B-1

Source RF signal: 5.5 kW (40 MHz)
Bias signal: 9 kV (400 kHz)
First processing gas: fluorocarbon gas (C₄F₆ gas and C₄F₈ gas) and O₂ gas (with fluorocarbon gas having highest flow rate among components of first processing gas)
Processing temperature: −20 °C

### Condition B-2

Source RF signal: 5.5 kW (40 MHz)
Bias signal: 9 kV (400 kHz)
Second processing gas: an HF gas, a fluorocarbon gas (C₄F₈ gas), an O₂ gas, and a halogen gas (with HF gas having highest flow rate among components of second processing gas)
Processing temperature: −20 °C

Line edge roughness (LER) of a portion near the bottom of each substrate was calculated based on FIGS. 10B and 10D. The LER of the portion near the bottom of the substrate in Example 1 was reduced to about 30% of the LER of the portion near the bottom of the substrate in Comparative Example 1.

### Example 2

In each of Example 2 and Comparative Example 2, the silicon-containing film SiF on the substrate W included multiple holes.

In Comparative Example 2, step ST2-2 alone was performed during etching. Comparative Example 2 was performed under condition C described below.

### Condition C

Source RF signal: 5.5 kW (40 MHz)
Bias signal: 9 kV (400 kHz)
Second processing gas: an HF gas, a fluorocarbon gas (C₄F₆ gas), a hydrofluorocarbon gas (CH₂F₂ gas), and a halogen-containing gas (with HF gas having highest flow rate among components of second processing gas)
Processing temperature: 0 ° C.
Gas supply time: 1200 seconds

In Example 2, step ST2-2 and step ST2-1 were performed during etching. In Example 2, a cycle including step ST2-2 and step ST2-1 in this order was repeated 19 times. Step ST2-2 was performed under Condition D-1 described below. Step ST2-1 was performed under Condition D-2 described below.

### Condition D-1

Source RF signal: 5.5 kW (40 MHz)
Bias signal: 9 kV (400 kHz)
Second processing gas: an HF gas, a fluorocarbon gas (C₄F₆ gas), a hydrofluorocarbon gas (CH₂F₂ gas), and a halogen-containing gas (with HF gas having highest flow rate among components of second processing gas)
Processing temperature: 0 °C
Gas supply time of each cycle: 60 seconds

### Condition D-2

Source RF signal: 5.5 kW (40 MHz)
Bias signal: 9 kV (400 kHz)
First processing gas: a fluorocarbon gas (a C₄F₆ gas and a C₄F₈ gas) and an O₂ gas
Processing temperature: 0 °C
Gas supply time of each cycle: 2 seconds

The holes in Example 2 and Comparative Example 2 were measured to determine bowing widths of the holes (maximum hole diameters) and positional variations in the bottoms of the holes. The positional variations in the bottoms of the holes refer to a variation (3σ) in the distances between the bottoms of the multiple holes. The bowing width in Example 2 was reduced to about 96% of the bowing width in Comparative Example 2. The positional variation in the bottoms of the holes in Example 2 was reduced to about 70% of the positional variation in the bottoms of the holes in Comparative Example 2. Although a trade-off is typically found between the bowing widths of the holes and the positional variation in the bottoms of the holes, both the bowing widths and the positional variation in the bottoms of the holes were improved in Example 2.

In the exemplary embodiment, the first processing gas supplied in step ST2-1 is free of a hydrogen fluoride gas or includes a hydrogen fluoride gas having a lower flow rate than the hydrogen fluoride gas included in the second processing gas. This can reduce a reaction product containing nitrogen produced in step ST2-1. This also allows efficient removal of the reaction product in step ST2-1.

In the exemplary embodiment, the second processing gas supplied in step ST2-2 is free of a fluorocarbon gas or includes a fluorocarbon gas having a lower flow rate lower than the fluorocarbon gas included in the first processing gas. This can reduce excess deposits on the mask or the sidewall of the recess in step ST2-2.

When the second processing gas includes a fluorocarbon gas, the first processing gas includes a fluorocarbon gas with a higher composition ratio of fluorine to carbon than the fluorocarbon gas included in the second processing gas in the exemplary embodiment. This allows efficient removal of the reaction product containing nitrogen in step ST2-1.

In the exemplary embodiment, the cycle including step ST2-1 and step ST2-2 is repeated multiple times. This can remove, for example, the reaction product in step ST2-1 before an excess amount of the reaction product containing nitrogen is deposited on the sidewall in step ST2-2. This allows etching in step ST2 without interfering with reaction products, thus reducing irregular features during etching.

In the exemplary embodiment, step ST2-2 is performed after step ST2-1, thus allowing protective films to be formed on the mask and the sidewall in step ST2-1. This can reduce bowing, or partial widening of the width of the recess, in step ST2-2.

In the exemplary embodiment, the processing time in step ST2-1 is the same as or shorter than the processing time in step ST2-2. This can reduce excess deposits on the mask or the sidewall of the recess.

### Second Embodiment

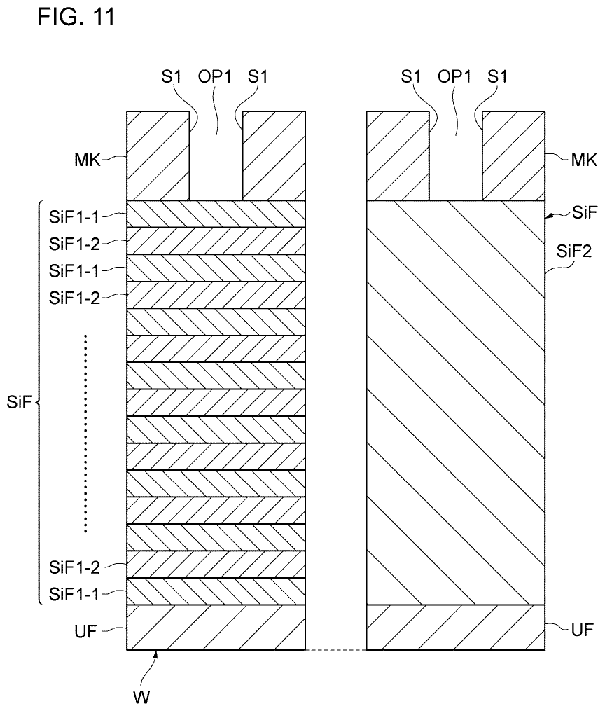

In one embodiment, the silicon-containing film SiF on the substrate W may include at least one film selected from the group consisting of a silicon oxide film, a silicon nitride film, and a film stack including a silicon oxide film and a silicon nitride film. FIG. 11 is a diagram of substrate W including two types of silicon-containing films, illustrating example structures. In one embodiment, the silicon-containing film SiF may include a first silicon-containing film SiF1 and a second silicon-containing film SiF2 different from the first silicon-containing film SiF1. The first silicon-containing film SiF1 may be a film stack including the silicon oxide films SiF1-1 and the silicon nitride films SiF1-2 alternately stacked on one another as in the first embodiment. The second silicon-containing film SiF2 may be a silicon oxide film. The silicon oxide film may be doped with nitrogen. The second silicon-containing film SiF2 may be a silicon nitride film.

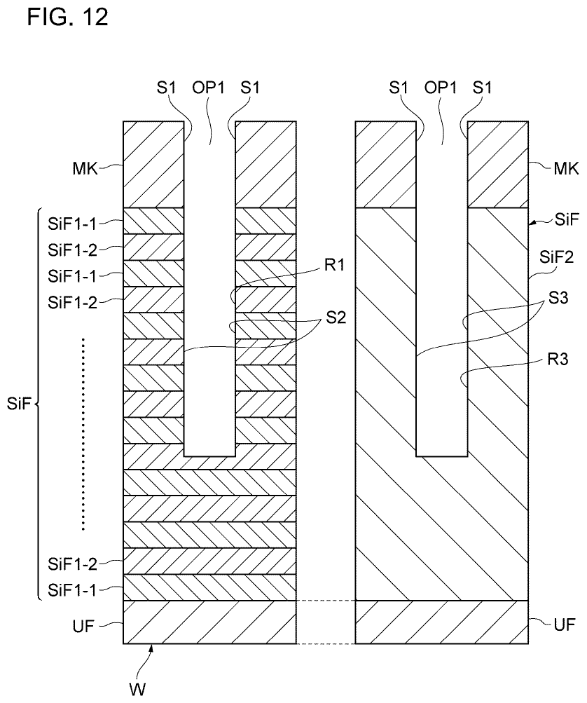

In one embodiment, step ST1 shown in FIG. 3 includes providing the substrate W including the first silicon-containing film SiF1 and the second silicon-containing film SiF2. Step ST2 includes etching the first silicon-containing film SiF1 and the second silicon-containing film SiF2. As shown in FIG. 12, step ST2 includes forming the recess R1 in the first silicon-containing film SiF1 and forming a recess R3 in the second silicon-containing film SiF2.

In one embodiment, a cycle including step ST2-1 and step ST2-2 may be repeated multiple times. In one embodiment, reaction products D1 containing nitrogen may be deposited on the sidewall S2 of the recess R1 in the first silicon-containing film SiF1 and a sidewall S3 of the recess R3 in the second silicon-containing film SiF2 in step ST2-2. The reaction products D1 deposited on the sidewall S2 of the recess R1 and the sidewall S3 of the recess R3 may be removed in step ST2-1.

In step ST2-2, the first silicon-containing film SiF1 may be etched faster than the second silicon-containing film SiF2. In step ST2-1, the second silicon-containing film SiF2 may be etched faster than the first silicon-containing film SiF1. The cycle including step ST2-1 and step ST2-2 may be repeated multiple times to reduce the difference in depth of etching between the first silicon-containing film SiF1 and the second silicon-containing film SiF2. The other conditions in the second embodiment may be the same as in the first embodiment described above.

The processing method according to the above embodiments may be performed in other types of plasma processing apparatuses such as a plasma processing apparatus that generates an inductively coupled plasma, a plasma processing apparatus that generates an ECR plasma, a plasma processing apparatus that generates a helicon wave plasma, or a plasma processing apparatus that generates a surface wave plasma, other than the capacitively coupled plasma processing apparatus.

The technique according to one exemplary embodiment of the present disclosure can reduce irregular features during etching.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

The embodiments of the present disclosure further include the aspects described below.

### Aspect 1

An etching method, comprising:
(a) providing a substrate including a silicon-containing film comprising nitrogen and a mask on the silicon-containing film, the mask including at least one opening; and
(b) etching the silicon-containing film to form a recess, (b) including
   (b1) etching the silicon-containing film with a first plasma generated from a first processing gas including a fluorocarbon gas, the fluorocarbon gas having a highest flow rate among components of the first processing gas, and
   (b2) etching the silicon-containing film with a second plasma generated from a second processing gas including a hydrogen fluoride gas.

### Aspect 2

The etching method according to aspect 1, wherein
the hydrogen fluoride gas has a highest flow rate among components of the second processing gas.

### Aspect 3

The etching method according to aspect 1 or aspect 2, wherein
the first processing gas is free of a hydrogen fluoride gas or includes a hydrogen fluoride gas having a lower flow rate than the hydrogen fluoride gas included in the second processing gas.

### Aspect 4

The etching method according to any one of aspects 1 to 3, wherein
the second processing gas is free of a fluorocarbon gas or includes a fluorocarbon gas having a lower flow rate than the fluorocarbon gas included in the first processing gas.

### Aspect 5

The etching method according to any one of aspects 1 to 4, wherein
the first processing gas includes two or more types of fluorocarbon gases with different composition ratios of fluorine to carbon.

### Aspect 6

The etching method according to any one of aspects 1 to 5, wherein
the second processing gas includes a fluorocarbon gas, and
the first processing gas includes the fluorocarbon gas with a higher composition ratio of fluorine to carbon than the fluorocarbon gas included in the second processing gas.

### Aspect 7

The etching method according to any one of aspects 1 to 6, wherein
at least one of the first processing gas or the second processing gas includes an oxygen-containing gas.

### Aspect 8

The etching method according to any one of aspects 1 to 7, wherein
at least one of the first processing gas or the second processing gas includes at least one gas selected from the group consisting of a noble gas, a nitrogen gas, a metal-containing gas, and a halogen-containing gas.

### Aspect 9

The etching method according to any one of aspects 1 to 8, wherein
(b) includes repeating a cycle including (b1) and (b2) a plurality of times.

### Aspect 10

The etching method according to aspect 9, wherein
(b2) is performed after (b1).

### Aspect 11

The etching method according to aspect 9 or aspect 10, wherein
(b2) includes depositing a reaction product including nitrogen on a sidewall of the recess, and
(b1) includes removing the reaction product deposited on the sidewall of the recess.

### Aspect 12

The etching method according to any one of aspects 9 to 11, wherein
(b1) includes forming a carbon-containing film on a sidewall of the recess.

### Aspect 13

The etching method according to any one of aspects 9 to 12, wherein
the recess has a lower line edge roughness after (b1) than after (b2) performed immediately before (b1).

### Aspect 14

The etching method according to any one of aspects 9 to 13, wherein
a processing time of (b1) is same as or shorter than a processing time of (b2).

### Aspect 15

The etching method according to any one of aspects 9 to 13, wherein
a processing time of (b1) is longer than a processing time of (b2).

### Aspect 16

The etching method according to any one of aspects 9 to 15, wherein
(b) includes changing a ratio of a processing time of (b2) to a processing time of (b1) with progress of etching of the recess.

### Aspect 17

The etching method according to any one of aspects 1 to 16, wherein
the silicon-containing film includes at least one film selected from the group consisting of a silicon oxide film, a silicon nitride film, and a film stack including a silicon oxide film and a silicon nitride film.

### Aspect 18

The etching method according to any one of aspects 1 to 17, wherein
the silicon-containing film includes a first silicon-containing film and a second silicon-containing film different from the first silicon-containing film,
the first silicon-containing film is a film stack including silicon oxide films and silicon nitride films alternately stacked on one another, and
the second silicon-containing film is a silicon oxide film.

### Aspect 19

The etching method according to any one of aspects 1 to 18, wherein
the mask includes at least one film selected from the group consisting of a silicon-containing film different from the silicon-containing film, a carbon-containing film, and a metal-containing film.

### Aspect 20

A substrate processing apparatus, comprising:
a chamber;
a substrate support in the chamber;
a plasma generator; and
a controller configured to perform control operations including
   (a) providing a substrate onto the substrate support in the chamber, the substrate including a silicon-containing film comprising nitrogen and a mask on the silicon-containing film, the mask including at least one opening, and
   (b) etching the silicon-containing film in the substrate provided on the substrate support to form a recess, (b) including
      (b1) etching the silicon-containing film with a first plasma generated by the plasma generator from a first processing gas including a fluorocarbon gas, the fluorocarbon gas having a highest flow rate among components of the first processing gas, and
      (b2) etching the silicon-containing film with a second plasma generated by the plasma generator from a second processing gas including a hydrogen fluoride gas.

The above embodiments are mere examples described for illustrative purposes and are not intended to limit the scope of the present disclosure. The embodiments may be modified in various manners without departing from the spirit and scope of the present disclosure. For example, one or more components in one embodiment may be added to the structure according to another embodiment. One or more components in one embodiment may be replaced with the corresponding one or more components in another embodiment.

What is claimed is:

1. An etching method, comprising:
(a) providing a substrate including a silicon-containing layer including nitrogen and a mask on the silicon-containing layer, the mask including at least one opening; and
(b) etching the silicon-containing layer to form a recess, (b) including
(b1) etching the silicon-containing layer with a first plasma generated from a first processing gas including a fluorocarbon gas, the fluorocarbon gas having a highest flow rate among components of the first processing gas, and
(b2) etching the silicon-containing layer with a second plasma generated from a second processing gas including a hydrogen fluoride gas.

2. The etching method according to claim 1, wherein
the hydrogen fluoride gas has a highest flow rate among components of the second processing gas.

3. The etching method according to claim 1, wherein
the first processing gas is free of a hydrogen fluoride gas or includes a hydrogen fluoride gas having a lower flow rate than the hydrogen fluoride gas included in the second processing gas.

4. The etching method according to claim 1, wherein
the second processing gas is free of a fluorocarbon gas or includes a fluorocarbon gas having a lower flow rate than the fluorocarbon gas included in the first processing gas.

5. The etching method according to claim 1, wherein
the first processing gas includes two or more types of fluorocarbon gases with different composition ratios of fluorine to carbon.

6. The etching method according to claim 1, wherein
the second processing gas includes a fluorocarbon gas, and
the first processing gas includes the fluorocarbon gas with a higher composition ratio of fluorine to carbon than the fluorocarbon gas included in the second processing gas.

7. The etching method according to claim 1, wherein
at least one of the first processing gas or the second processing gas includes an oxygen-containing gas.

8. The etching method according to claim 1, wherein
at least one of the first processing gas or the second processing gas includes at least one gas selected from the group consisting of a noble gas, a nitrogen gas, a metal-containing gas, and a halogen-containing gas.

9. The etching method according to claim 1, wherein
(b) includes repeating a cycle including (b1) and (b2) a plurality of times.

10. The etching method according to claim 9, wherein
(b2) is performed after (b1).

11. The etching method according to claim 9, wherein
(b2) includes depositing a reaction product including nitrogen on a sidewall of the recess, and
(b1) includes removing the reaction product deposited on the sidewall of the recess.

12. The etching method according to claim 9, wherein
(b1) includes forming a carbon-containing layer on a sidewall of the recess.

13. The etching method according to claim 9, wherein
the recess has a lower line edge roughness after (b1) than after (b2) performed immediately before (b1).

14. The etching method according to claim 9, wherein
a processing time of (b1) is same as or shorter than a processing time of (b2).

15. The etching method according to claim 9, wherein
a processing time of (b1) is longer than a processing time of (b2).

16. The etching method according to claim 9, wherein
(b) includes changing a ratio of a processing time of (b2) to a processing time of (b1) with progress of etching of the recess.

17. The etching method according to claim 1, wherein
the silicon-containing layer includes at least one layer selected from a group consisting of a silicon oxide layer, a silicon nitride layer, and a layer stack including a silicon oxide layer and a silicon nitride layer.

18. The etching method according to claim 1, wherein
the silicon-containing layer includes a first silicon-containing layer and a second silicon-containing layer different from the first silicon-containing layer,
the first silicon-containing layer is a layer stack including silicon oxide layers and silicon nitride layers alternately stacked on one another, and
the second silicon-containing layer is a silicon oxide layer.

19. The etching method according to claim 1, wherein
the mask includes at least one layer selected from the group consisting of a silicon-containing layer different from the silicon-containing layer, a carbon-containing layer, and a metal-containing layer.

20. A substrate processing apparatus, comprising:
a chamber;
a substrate support in the chamber;
a plasma generator; and
controller circuitry configured to perform control to
(a) provide a substrate onto the substrate support in the chamber, the substrate including a silicon-containing layer including nitrogen and a mask on the silicon-containing layer, the mask including at least one opening, and
(b) etch the silicon-containing layer in the substrate provided on the substrate support to form a recess, (b) including
(b1) etch the silicon-containing layer with a first plasma generated by the plasma generator from a first processing gas including a fluorocarbon gas, the fluorocarbon gas having a highest flow rate among components of the first processing gas, and
(b2) etch the silicon-containing layer with a second plasma generated by the plasma generator from a second processing gas including a hydrogen fluoride gas.
